(19) United States
(12) Patent Application Publication
(10) Pub. No.: US 2007/0071249 A1
(43) Pub. Date: Mar. 29, 2007

(54) System for the simulation of a room impression and/or sound impression

(76) Inventors: Friedrich Reining, Vienna (AT); Hannes Breitschadel, Vienna (AT)

Correspondence Address: BRINKS HOFER GILSON & LIONE, P.O. BOX 10395, CHICAGO, IL, 60610, US

(21) Appl. No.: 11/475,851

(22) Filed: Jun. 27, 2006

(30) Foreign Application Priority Data
Jun. 28, 2005 (EP) EP 05 450 116.8

(51) Int. Cl. H03G 3/00

(52) U.S. Cl. 381/63

(57) ABSTRACT

A system simulates a room impression and/or sound impression to a listener. The simulation includes recreating a sound at a particular location. An audio signal is combined with a space impulse response from that location. The space impulse response and audio signal are split into more than one sub-bands and combined to produce an aural output.

### BACKGROUND OF THE INVENTION

### Priority Claim

This application claims the benefit of priority from European Patent Application No. EP 05450116.8, filed Jun. 28, 2005, which is incorporated by reference.

1. Technical Field.

This application relates to a system that simulates a spatial and/or acoustic effect with a reproduction of sound.

2. Related Art.

The fidelity of an acoustic pattern may offset the reproduction of the sound or acoustic pattern. In a concert hall, opera, or church, the room impression or sound impression left with a listener may be different from the impression that a recording gives to a different listener. An environment may create unique acoustic effects. To accurately reproduce a sound, these nuances should be duplicated.

In some systems, recordings may be made at many different locations in a room. Audio processing of signals may be complicated and expensive. If the amount of data needed to reproduce sound is high, the overall calculations needed to process the data may be significant. If a recreation needs to be done in real time or with minimum latency the processing may be further complicated. As a result, the recording, bringing together, and calculation of such a high quantity of data may be complicated and expensive. There exists a need for a simplified system to recreate acoustics for a room impression.

### SUMMARY

A system that simulates the acoustics of a room or generates a sound impression may simplify the determination of an impulse response to a measurement signal. A simulation recreates a sound at a particular location. An audio signal may be combined with a space impulse response from that location to recreate the sound. The space impulse response and audio signal may be filtered into two or more sub-bands and combined to produce an audio output that simulates a sound impression.

The sub-bands may be processed to improve the sound quality. The space impulse response may be reduced through dilution. The audio signal may be split up or filtered into a number of sub-bands. The sub-bands may be convolved, sampled, and synthesized to produce an audio output.

Other systems, methods, features and advantages of the invention will be, or will become, apparent to one with skill in the art upon examination of the following figures and detailed description. It is intended that all such additional systems, methods, features and advantages be included within this description, be within the scope of the invention, and be protected by the following claims.

### BRIEF DESCRIPTION OF THE DRAWINGS

The invention may be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is a block diagram of a system that simulates the acoustics of a room.

FIG. 2 is a diagram of an energy distribution of an exemplary space impulse.

FIG. 3 is a diagram of a frequency distribution of an exemplary space impulse response.

FIG. 4 is a diagram of an energy course.

FIG. 5 is another diagram of an energy course.

FIG. 6 is a diagram of a frequency distribution of an exemplary space impulse response.

FIG. 7 is a diagram of a filter bank.

FIG. 8 is a diagram of a space impulse response.

FIG. 9 is a diagram of a space impulse response with latency compensation.

FIG. 10 is a diagram of an amplitude of an impulse response.

FIG. 11 is another diagram of an amplitude of an impulse response.

FIG. 12 is another diagram of an amplitude of an impulse response.

FIG. 13 is another diagram of an amplitude of an impulse response.

FIG. 14 is another diagram of an amplitude of an impulse response.

FIG. 15 is another diagram of an amplitude of an impulse response.

### DETAILED DESCRIPTION OF THE PREFERRED EMBODIMENTS

A simulation of spatial acoustic events may occur through a convolution of an audio signal with a binaural space impulse response. The binaural space impulse response may be measured at any specific reception site in a room. A room impression may be of any site or location and may identify the environment from which the acoustic effects may be reproduced. In U.S. Pat. No. 5,142,586, which is incorporated by reference, an electroacoustical system processes sound emitted by one or more sound sources in a room. Sound may be recorded through multiple devices that generate signals that are processed and sent to multiple loudspeakers positioned across a room. The system attempts to replicate any sound source position for any listener position in a room.

A binaural space impulse response may include two impulse responses. One impulse response is correlated to one ear and the other impulse response is correlated to another ear. The characteristics of the room and the reception characteristics of the human ears may form a linear causal transmission system, which may be described by the space impulse responses in a predetermined time range.

The space impulse response may comprise a continuous time signal w(t) and may be digitalized. From w(t), the time-discrete representation becomes w(n), where n is the time index for the sampling values, which is linked with the time by t=nτ, and τ is the duration of period of the sampling frequency.

An individual space impulse response is approximately the system response to an acoustic impulse, whose, time length may be a period of about double the upper limit frequency of the audio signal. The convolution of an audio program with the binaural space impulse responses produces a signal suitable for electro acoustic reproduction. The electro acoustic reproduction may approximate a correct sound reproduction that may be perceived or heard. The hearing experience is may seem as if it was experienced by a person at the site in which the actual spatial-acoustic event originally took place.

A measuring signal that is picked up at the hearing site with a microphone or device that converts audio into analog or digital signals is transmitted at the site of the sound source. The space impulse response is obtained from the received signal. If an impulse whose time is about equal to a period of about double the frequency of the upper frequency limit of the audio signal range is used as a measurement signal, then the received signal is about equal to the space impulse response h(t). Since the interference distance is small with this method, a longer measurement signal may be preferred and the space impulse response may be determined by computation there from. The response to the measurement signal may be a continuous signal in time, and may be digitized for further processing. The recorded audio data may be stored in any medium, including but not limited to a compact disc, digital video disc, high-definition disc, blu-ray disc, or any digital format, such as MP3, WMA, or WAV.

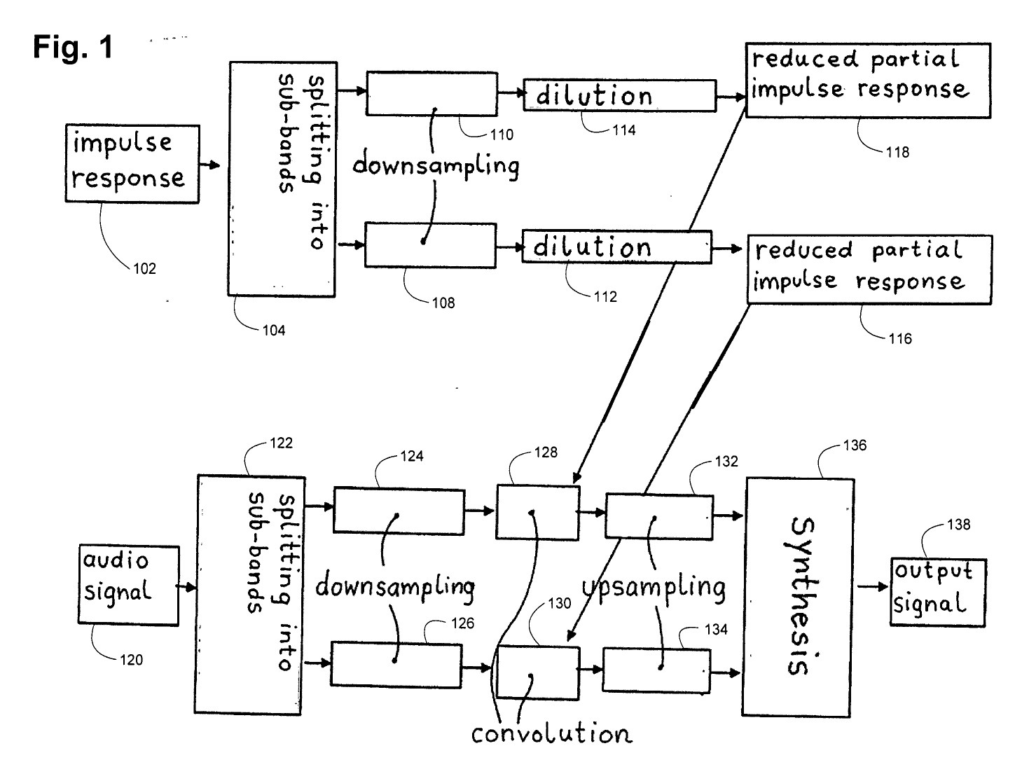

FIG. 1 illustrates a space impulse response split into two sub-bands and an audio signal split up into two sub-bands. The respective sub-bands are processed. The impulse sub-bands may be downsampled and diluted, before being combined or convoluted, upscaled, and synthesized to produce an output signal. In alternate systems, the space impulse response 102 may split into any number of sub-bands. The splitting may occur in a filter bank 104. A filter bank 104 may comprise one or more parallel high pass, low pass, or band pass filters. FIG. 6 is a frequency response of an exemplary filter bank 104. The filter bank 104 may be used to split up a discrete signal into various sub-band ranges. As shown in FIG. 1, the filter bank 104 splits the impulse response 102 into two sub-bands.

In FIG. 1, the individual sub-bands may be downsampled 108 and 110. The downsampling 108 and 110 may allow the signals to be sampled at about double the frequency of the bandwidth. The sampling rate may correspond to the Nyquist-Shannon sampling theory. The continuous signal may be sampled at a frequency greater than twice the maximum frequency of the audio signal. For an individual frequency band having a lower and upper frequency limit, the sampling frequency may be twice the upper frequency limit of the signal bandwidth.

Following the downsampling 108 and 110 of the individual sub-band signals, a separate dilution 112 and 114 or reduction of the individual partial impulse responses occurs through dilution logic. Dilution or reduction may indicate that at least certain ranges of the partial impulse responses are set approximately to zero. The criteria for which values of the partial impulse response are set approximately to zero may differ depending on the particular system. The criteria may depend on the available calculation power or on the desired quality of the simulation of space and acoustics. The dilution logic 112 and 114 or reduction of the sub-band specific space impulse responses may occur through the method disclosed in U.S. Pat. No. 5,544,249 (or in European Patent No. 0641143 B1, belonging to the same patent family), both of which are incorporated by reference.

A space impulse response may be divided into several time sections. The values of the individual sections may be compared with a time dependent threshold value. Values of the space impulse responses that exceed the threshold value may be processed. The remaining part of the space impulse response below the threshold value may be attenuated or minimized. Attenuating sections that are below a predetermined threshold may result in a diluted impulse response.

The predetermined threshold value used for dilution may be associated with a space impulse response in a time-dependent manner. The predetermined threshold value may be dependent on a transit index “n” for the sampling values. The predetermined threshold value may be selected so that it has its greatest area near the beginning of the space impulse response and may subside toward the end of the space impulse response. Accordingly, wide ranges of the space impulse responses may be minimized or become approximately zero. However, the ranges of the space impulse response that may be minimized or dissipated to approximately zero may not affect the hearing experience of an audio program convolved with the space impulse response. Then time ranges may not be perceptible to a person because of physiological and psychoacoustic reasons. In some systems, only those time sections of the space impulse response that may be heard are extracted by the dilution logic to produce the same room impression and sound impression for a listener. Those time ranges of the space impulse response that are heard by a human may be used for the corresponding space and for the original-fidelity simulation in a convolution of an audio signal.

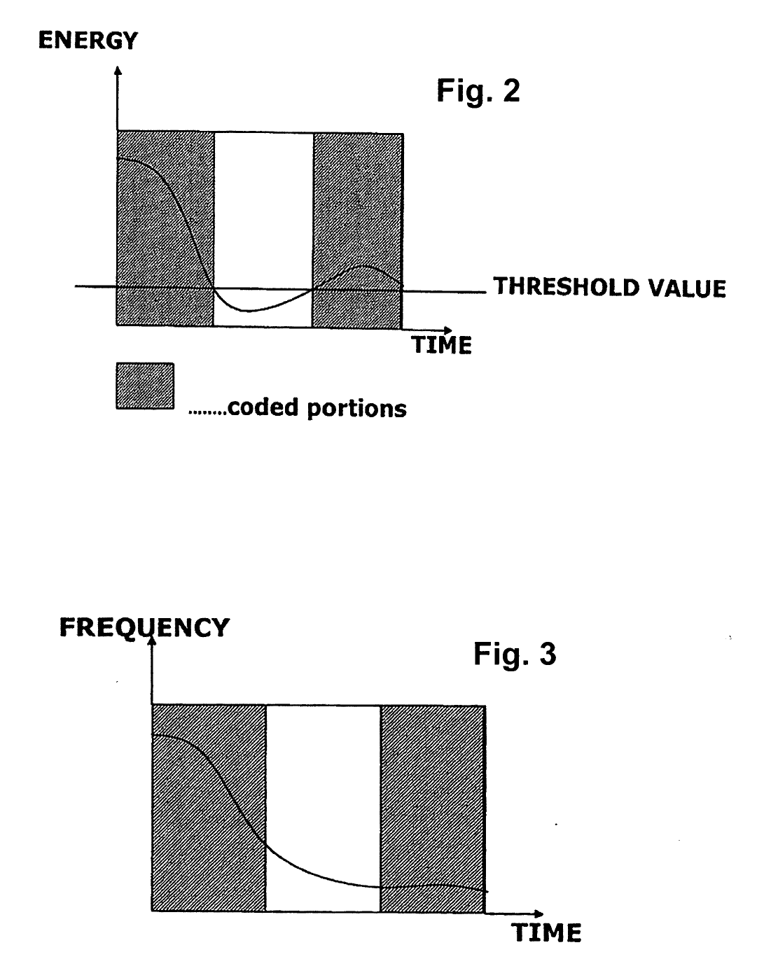

FIG. 2 is a diagram of the energy of a space impulse response over time. For the determination of the diluted space impulse response, a predetermined threshold value may be used and the values of the space impulse response below this threshold value may be minimized or set approximately to zero. In alternate systems, only the shaded time ranges may be coded to a greater extent. In one system, a threshold value for the amplitude is almost squarely proportional to the energy density. In other systems, the threshold value may be chosen differently. The energy values are positive in contrast to the amplitude of the signal.

FIG. 3 is a frequency response obtained from a space impulse response. Near the beginning of the space impulse response, all frequencies are represented, however, later in time high frequencies subside leaving predominantly low frequencies. The higher frequencies may be strongly dampened by walls, chairs, carpets, niches, etc., whereas low frequencies may be reflected. This may result in a shift of the energy to low frequencies in the subsidence of the space impulse response. The dampening of high frequencies may lead to a bass dominated acoustical pattern.

If two time portions of FIG. 3 (as shown shaded and corresponding to those from FIG. 2) are subjected to a coding, then an excessively large calculation may be needlessly performed for the right side of the two ranges. This may occur despite the fact that only low frequencies were to be taken into consideration. If the convolution algorithm does not consider whether only low or high frequencies are present, there may be unnecessary calculations.

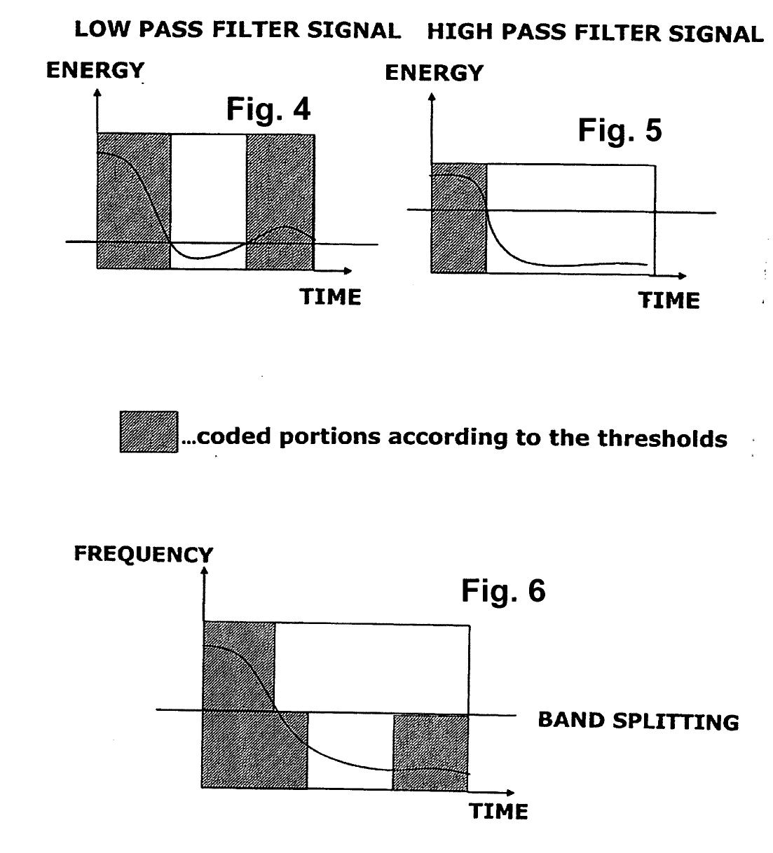

In FIG. 1, the partial impulse responses 116 and 118 may be compared with a predetermined threshold value for energy (or any equivalent, such as amplitude), which may be time-dependent, and changed in such a way that all values lying below the threshold value are minimized or set approximately to zero. As shown in FIGS. 4, 5 and 6 there may be one splitting into two sub-bands. FIG. 4 illustrates an energy course of a low-pass signal, with a threshold value. The ranges (shaded) may be coded in accordance with a threshold value. FIG. 5 illustrates an energy course of a high-pass signal, combines with the threshold value, and the ranges coded in accordance with the threshold value. The threshold criteria used for the individual sub-bands may be different and independent of one another. Alternate systems generate a reduced partial impulse response for one frequency band, whereas the other partial impulse response(s) may be used for the convolution unchanged.

The predetermined threshold values to be specified may be adapted to a specific frequency course of an impulse response of a certain space. Based on the system of the frequency representation from FIG. 6, corresponding to FIGS. 4 and 5, one may see that by the selection of the sub-band-specific threshold values, the coded ranges may decrease, in comparison to FIG. 3, which reduces the processing expense.

The sub-band-specific space impulse responses may be divided or subdivided into individual time sections, such that different threshold values may be correlated with the individual time sections. Some systems compare a continuous, time-dependent function for the threshold value with impulse responses. In convolution with a desired audio signal, those time sections of the partial impulse response that exceed the threshold value may be used. The remaining sections may be minimized or set approximately to zero. Accordingly, a diluted or reduced partial impulse response may be produced for each sub-band. A diluted impulse response may be obtained for high frequencies and low frequencies. Partial impulse responses may comprise another basis for the simulation of a spatial and acoustic effect.

For reduction of a partial impulse response, a threshold value for an amplitude or energy may be determined. The predetermined threshold value may extend over at least a section of the length of a determined partial impulse response. Through comparison with the predetermined threshold value, a reduced partial impulse response may be produced. The partial impulse response may have only parts of the determined partial impulse response, in which the momentary amplitude or energy lies above the predetermined threshold value. For those parts of the determined partial impulse response whose instantaneous amplitude or energy lies below the predetermined threshold, the reduced partial impulse response may be minimized or set approximately to zero.

In alternate systems, other criteria may be used, according to which certain ranges of the partial impulse responses may be minimized or set approximately to zero. A partial impulse response may be automatically minimized or set approximately to zero beyond a certain time limit or interval. Alternately, those ranges of the partial impulse responses that may have frequencies below a predetermined frequency, may be minimized or set approximately to zero. The space impulse response may also be modeled or synthesized. Sections of these signals may be minimized or set approximately to zero, while other sections are changed. When a section of the partial impulse response is minimized or set approximately equal to zero the amount and time of the calculation may be reduced.

In one system, a comparator may be used to attain a reduced partial impulse response. The comparator may compare the predetermined threshold value with a momentary value of the partial impulse response. If the overall calculation is also to be taken into consideration, then the sampling values of the remaining fractions of the reduced partial impulse response may be determined through a coefficient counter. The obtained numerator value may be compared through the comparator using a limit value determined by function or calculation. If the limit is not exceeded, additional fractions of the space impulse responses may be coded, or the threshold value may be reduced.

An arbitrary audio signal may be used with a spatial and acoustic effect through a convolution with the impulse response or a partial impulse responses. In FIG. 1, the input audio signal 120 may split into several sub-bands by software or hardware that selectively passes certain elements of a signal and eliminates or minimizes others in filter bank 122. The number and limit frequencies of these sub-bands may relate to those used for the determination of the individual partial impulse responses. Once filtered, the signals are sampled through downsampling logic 124 and 126. Convolutions 128 and 130 process the individual sub-band before the sub-bands are processed by the upsampling logic 132 and 134.

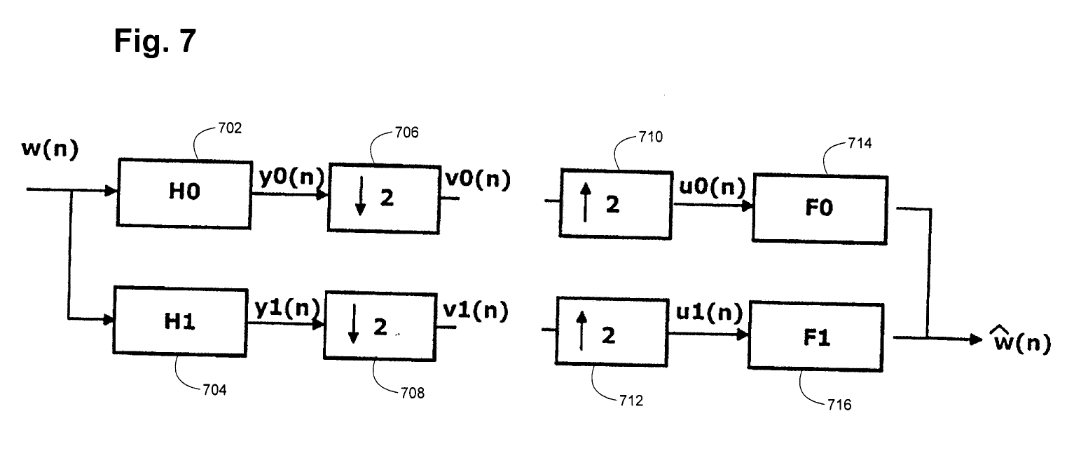

The free space, shown in FIG. 7, between the downsampling logic and the upsampling logic may represent a node that couples algorithms or coding logic between the input and output. Each individual sub-band signal may be convolved with the corresponding partial impulse response. The partial impulse responses for the individual frequency ranges for the convolution 128 and 130 may be determined as described above. The determination of the coefficients for the space impulse response for a certain room at a certain location in this room may occur at a signel point in time. The coefficients may be available for some or all of the arbitrary audio signal that provided the spatial effect, preferably as a filter coefficient stored in a convolution filter.

After the upsampling logic 132 and 134, the synthesis of the individual sub-bands to a full band may occur. A signal may be then provided with the spatial and/or acoustic effect. An increase in the cycle frequency may be increased by doubling the upper frequency limit of the signal according to the Nyquist theorem. In the subsequent synthesis of the individual sub-bands to a total signal, a perfect merger may occur.

In FIG. 7, w(n) may represents the input signal 120 and ŵ(n) may represent the output signal 138. The low pass of the analysis filter bank is designated by HO 702 and the high pass is designated by HI 704. y0(n) comprises the sub-band signal filtered with the low pass filter 702 and y1(n) comprises the sub-band signal filtered with the high pass filter 704. The signals may be downsampled in 706 and 708. The corresponding downsampled signals may comprise v0(n) and vl(n), respectively. In FIG. 7, the signals u0(n) or u1(n) are formed after the signals are upsampled 710 and 712. The low pass filter FO 714 and the high pass Fl 716 may be part of the synthesis filter 136. If the open nodes are bridged, FIG. 7 may represents a filter bank with a nearly perfect reconstruction. In particular, if the output signal ŵ(n) is identical with the input signal w(n), then no information is lost.

In one system, that extinguishes the aliasing components. A Z transformation may be used as in: FO(z)*HO(−z)+Fl(z)H1(−z)=0, and for a distortion-free reconstruction due to downsampling and upsampling, a Z transformation may comprise: FO(z)*HO(z)+Fl(z)Hl(z)=2z⁻¹. The aforementioned Z transformation may be used in digital signal processes, to transform discrete time signals into a complex signal in the frequency domain (that may be similar to the Fourier transformation for time-continuous signals). Alternate systems may use analogous filter banks and comparators.

In FIG. 7, the space impulse responses or the audio signals may be split into two sub bands. In alternate systems, any number of sub-bands may be processed. Depending on the time dependency of the frequency distribution for a specific space, the number and the upper and lower limit frequencies of the individual sub-bands may be varied to attain an original-fidelity simulation of the spatial/acoustic effect. The acts that split the sub-band for the sub-band and the synthesis of the sub-bands may result in reduced calculations if the space impulse response has a certain length. The longer the range in which only low frequencies occur, the more efficient the required calculation or process may be.

To reduce latency a full band impulse response may be split into two regions. The splitting point may be defined by the latency caused by the filterbank. The audio signal may be fed to a filterbank and to a convolver, that convolves the signal with the full band impulse response portion up to that splitting point. The output signal may be the sum of the output signal of the full band convolver and the output signal of the filter bank.

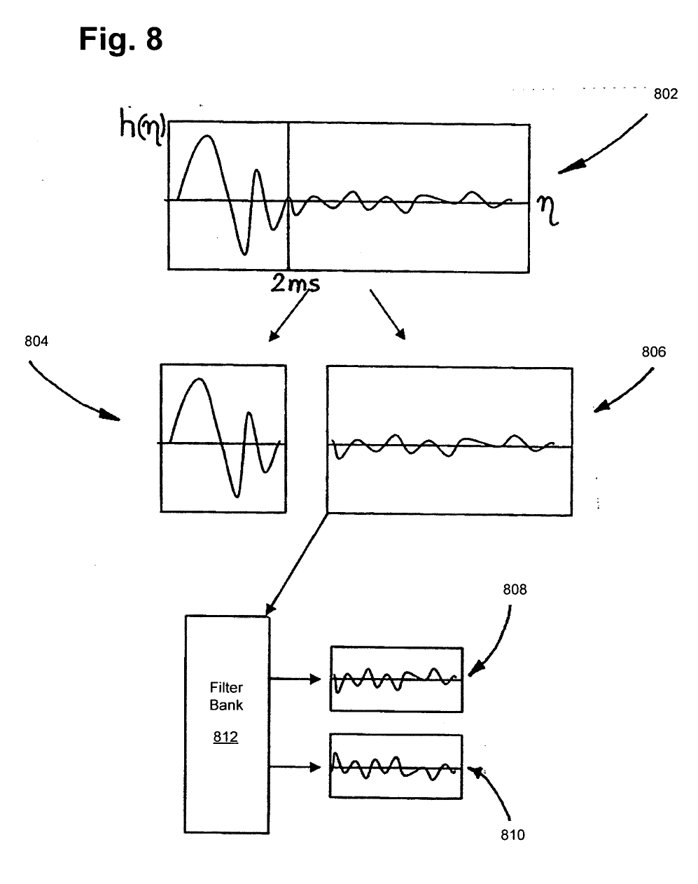

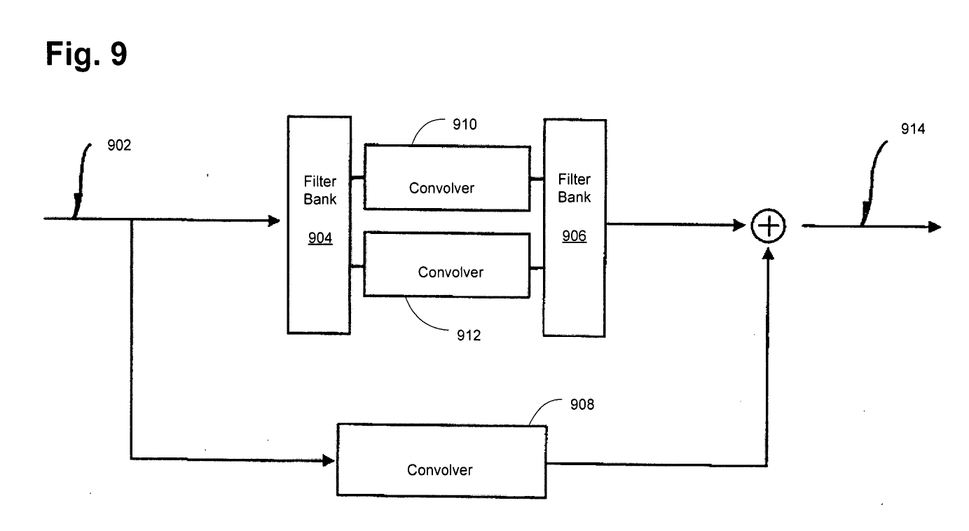

Some methods convolve a non split audio signal with a first portion of the full space impulse response. The second portion of the full space impulse response may be processed as explained above. Such a convolved audio signal may be added to the signal to compensate for the latency occurring due to calculation processes. This system is described in FIGS. 8-9.

A system that splits one portion of the space impulse response i is shown in FIG. 8. In this figure, the space impulse response h(η) 802 is split into two regions. (η) may be the time index for the sampling values, which is linked with the time by t=ητ. τ may be the duration of period of the sampling frequency. The first portion 804 extends from the beginning to the splitting point and the second portion 806 extends from the splitting point to the end of the space impulse response 802. The splitting point may correspond to the latency caused by the filter bank. This may occur at about two milliseconds as shown in 802. The portion 806 of the space impulse response 802 with η corresponding to a time greater than about 2 ms is split by filterbank 812 according to the system discussed above, resulting in two sub-bands and two partial impulse responses 808 and 810, which may be diluted or reduced as in FIG. 9.

In FIG. 9, the audio signal 902 is passed through the filterbank 904 and a convolver 908. The convolver 908 convolves the audio signal 902 with the portion 804 of the space impulse response 802. The filterbank 904 selectively passes the audio signal into sub-bands. The convolver 910 may convolve the first partial audio signal with the reduced partial impulse response 808, and the convolver 912 convolves the second audio signal with the reduced partial impulse response 810. Additional processing may reduce the partial impulse responses, and downsample and/or upsample the signal.

The two resulting signals may be added to form the desired audio signal that provides the room and/or listening impression. Through this method the delay caused by the filterbanks 904 and 906 may be compensated. However, additional calculation power may be used due to convolving audio signal 902 with the portion 804 of the space impulse response. A calculation savings may be achieved due to the splitting of the main portion of the impulse response into sub-bands and processing the partial impulse responses within these sub-bands.

Since a time index may be stored for each coefficient, the approximately zero values between two ranges may not need to be calculated in some methods. Accordingly, during the calculation, storage units for the signal to be convolved may be present in a full impulse response length regardless of whether a sub-band or full band is used. The number of the multiplications and additions may still be reduced, to the extent coefficients may not be set approximately to zero.

The systems described above may include convolution calculations, such as the filtering of a signal with filter coefficients, in which there is a consideration of the gain in calculation efficiency in relation to quality losses by the omission of information. Based on the time/frequency behavior of the impulse response to be convolved, some systems estimate in advance the extent to which quality losses may be expected with certain predetermined threshold values. Accordingly, those parts of the space impulse response that may not cause perceptible quality losses may be omitted. The omitted information may depend on the time frequency behavior of the impulse response to be convolved and how much calculation effort may be saved.

Finally, some other variants may show the time dependence of a predetermined threshold value used in the dilution of the partial impulse responses. In contrast to FIGS. 2, 4 and 5, FIGS. 10, 11, FIGS. 12, 13, and FIGS. 14, 15 show the impulse responses h(η) in amplitude representation. The energy corresponds to the square of the amplitude.

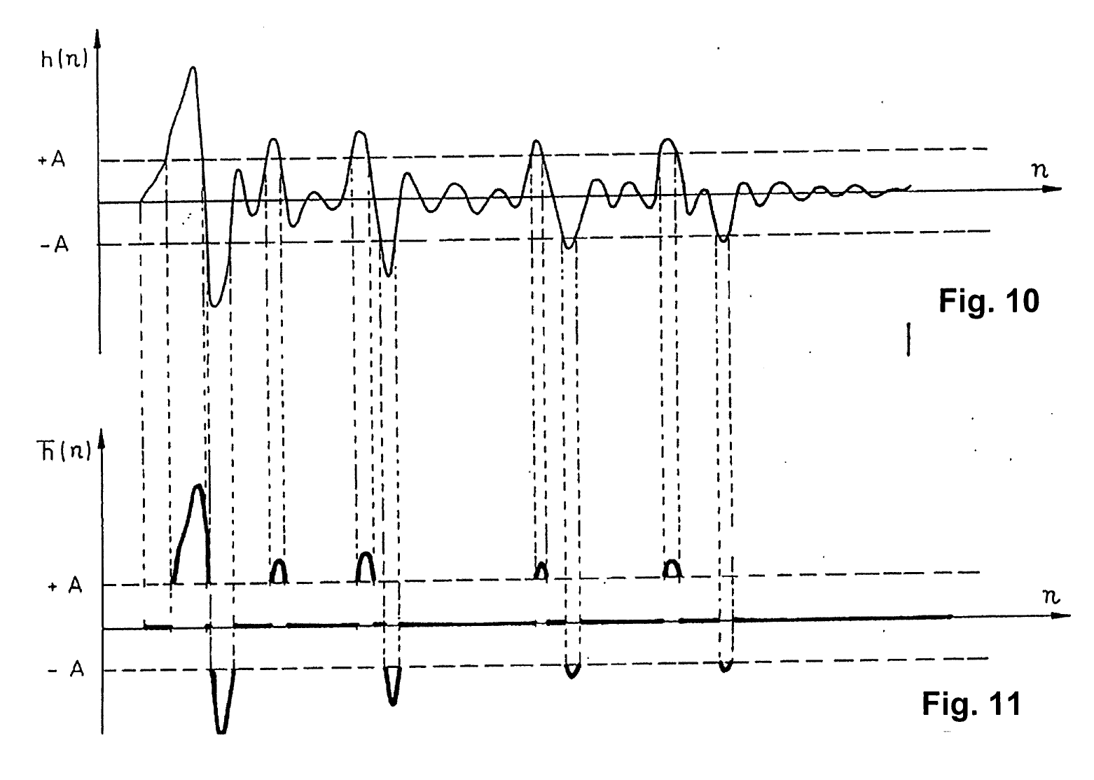

As FIGS. 10 and 11 illustrate the selection of the signal fractions of the determined partial impulse responses. The fractions of the determined partial impulse response that lie below a determined threshold value A are minimized or set substantially to zero. Likewise, partial impulse response that are less than zero, but greater than −A are minimized or set substantially to zero. The portions set substantially to zero remain unconsidered with respect to the later convolution process, while the signal values exceeding the threshold values A, −A or the corresponding sampling values may be included in the reduced partial impulse response with an unchanged amplitude.

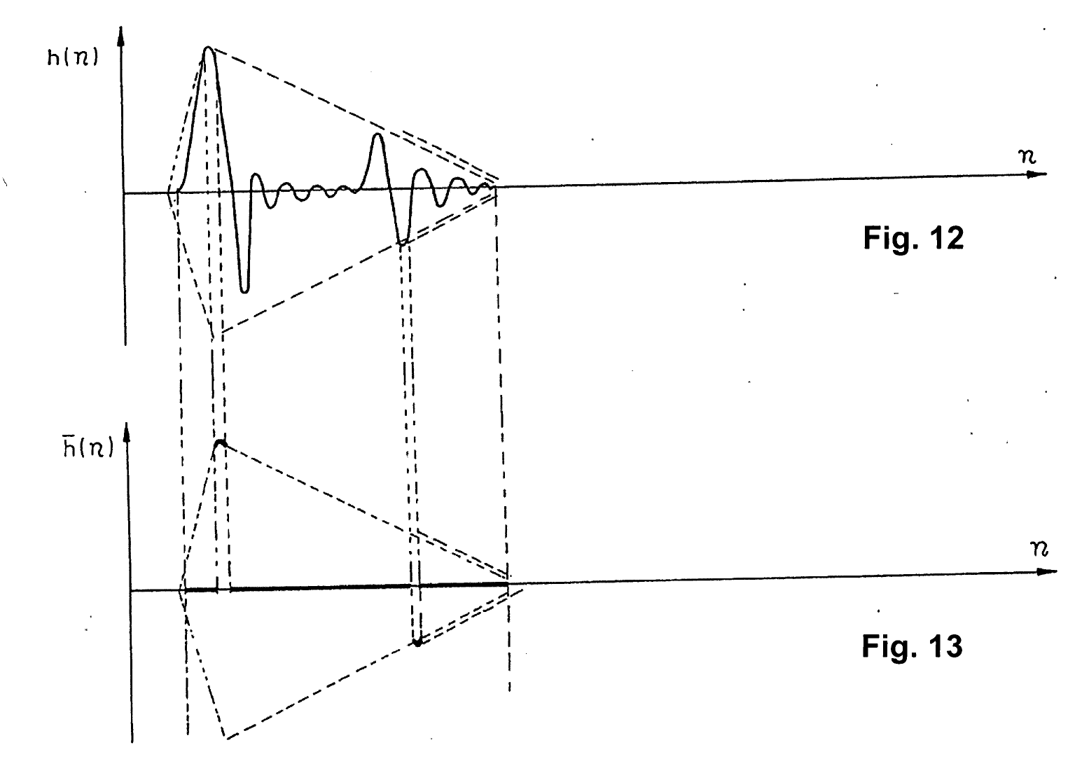

FIGS. 12 and 13 illustrate a selection may also be possible with criteria according a concealing occurrence. Accordingly, those fractions from the determined partial impulse response that are not perceptible to human hearing may not need to be considered. In accordance with the available information, the concealed fractions may be minimized or removed from the convolution. Ranges of pre-concealment and post-concealment may be distinguished. Those are time periods in which signals may be below a level limit, as they are shown in FIG. 12, are no longer perceptible, in comparison to a main signal. Therefore, as shown in FIG. 13, the main signal is the only perceptible signal, so the remaining portions are concealed.

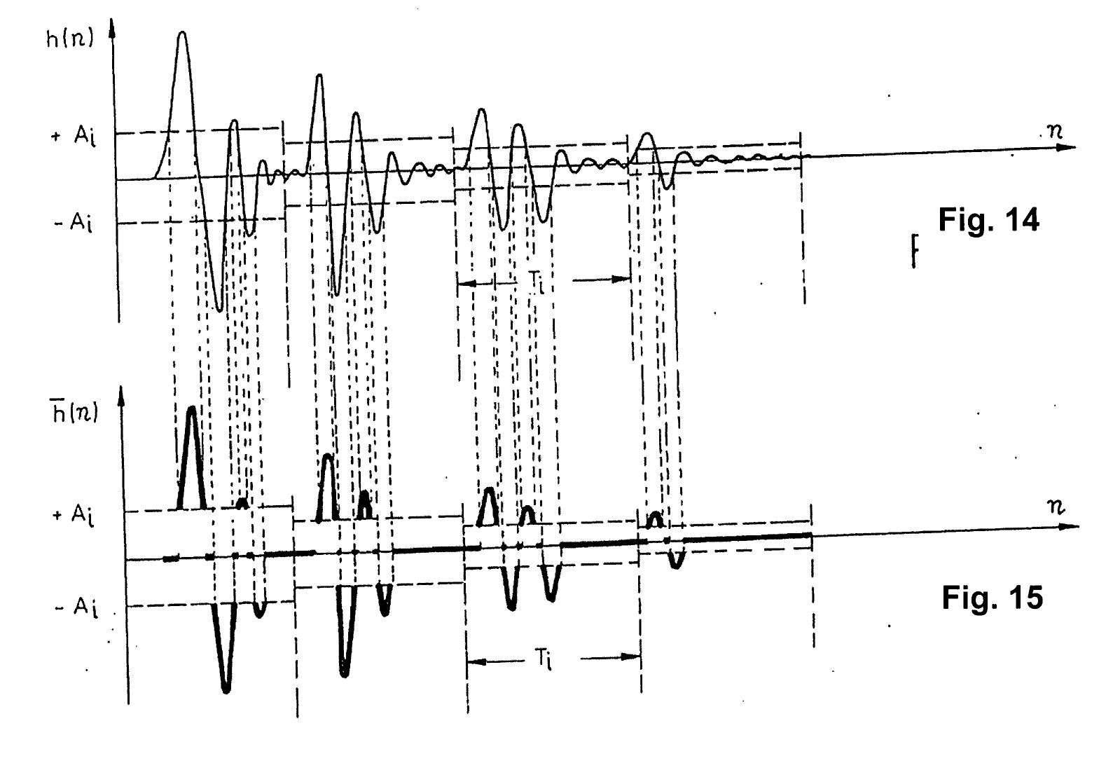

FIGS. 14 and 15 illustrate how as the threshold value is diminished stepwise, the signal fractions for the simulation are removed. There are four segments of Tⱼ length that are shown, with each segment having a different amplitude Aⱼ and −Aⱼ. As the absolute value of the amplitude decreases, the signal fractions are removed. In the last segment, the majority of signal fraction is removed or set substantially to zero, while only a small portion is above A and below −A.

While various embodiments of the invention have been described, it will be apparent to those of ordinary skill in the art that many more embodiments and implementations are possible within the scope of the invention. Accordingly, the invention is not to be restricted except in light of the attached claims and their equivalents.

We claim:

1. A method for simulating a sound impression, the method comprising:
providing a space impulse response;
splitting a portion of the space impulse response into at least two sub-bands;
producing at least one reduced partial impulse response for at least one of the at least a portion of the space impulse responses; and
convolving an audio signal with the at least one reduced partial impulse response.

2. The method according to claim 1 where the sound impression occurs at a particular location and the space impulse is provided for that location

3. The method according to claim 1 where the reduced partial impulse response is produced through a dilution.

4. The method according to claim 3 where the dilution comprises setting the reduced partial impulse response approximately to zero.

5. The method according to claim 4 where one of the reduced partial impulse response is set approximately to zero if it lies below a predetermined threshold level.

6. The method according to claim 5 where the threshold level for each of the reduced partial impulse response is different.

7. The method according to claim 1 where convolving comprises:
splitting the audio signal into at least two sub-bands of the audio signal;
downsampling the at least two sub-bands of the audio signal; and
convolving each of the at least two sub-bands of the audio signal with one of the reduced partial impulse responses.

8. The method according to claim 7 where the number of the sub-bands of the space impulse response comprises the same number of the sub-bands of the audio signal.

9. The method according to claim 8 where convolving comprises convolving each of the sub-bands of the space impulse response with one the sub-bands of the audio signal.

10. The method according to claim 7 further comprising:
upsampling the convolved sub-bands;
synthesizing the convolved sub-bands; and
producing an output signal.

11. The method according to claim 1 where the producing the reduced partial impulse response further comprises:
downsampling the at least two sub-bands; and
diluting the at least two sub-bands.

12. A system that reproduces a sound impression comprising:
a filter bank configured to split an audio signal into sub-bands;
a convolutor configured to receive the sub-bands and receive reduced partial impulse responses, where the convolutor combines at least one of the sub-bands with at least one of the impulse responses to produce at least one combined signal; and
a synthesizer configured to the receive the at least one combined signal and produce an output signal.

13. The system according to claim 12 further comprising:
an impulse filter bank configured to split an impulse response into reduced partial impulse responses;
a dilutor configured to dilute at least one of the reduced partial impulse responses; and
an interface to transmit the diluted reduced partial impulse responses to the convolutor.

14. The system according to claim 13 further comprising a downsampler configured to downsample the reduced partial impulse responses.

15. The system according to claim 13 where the dilutor sets the reduced partial impulse responses to approximately zero.

16. The system according to claim 15 where the reduced partial impulse responses set to approximately zero is below a threshold value.

17. The system according to claim 12 further comprising:
a downsampler configured to downsample the sub-bands; and
an upsampler configured to upsample the at least one combined signal.

18. The system according to claim 12 where the output signal is a reproduction of the sound impression from at least one location.

19. The system according to claim 12 where the sub-bands are in a one-to-one ratio with the reduced partial impulse responses.

20. The system according to claim 19 where each of the combined signals corresponds to one pair of the sub-band and reduced partial impulse response.

21. A method for recreating a sound impression comprising:
means for splitting an impulse response and audio signal into sub-bands;
means for processing the sub-bands; and
means for convoluting the sub-bands to produce an output signal that recreates a sound impression.
